(19) United States
(12) Patent Application Publication
(10) Pub. No.: US 2026/0063736 A1
(43) Pub. Date: Mar. 5, 2026

(54) MAGNETORESISTIVE SENSOR

(71) Applicant: Infineon Technologies AG, Neubiberg (DE)

(72) Inventors: Simon MENDISCH, Eichenau (DE); Wolfgang RABERG, Sauerlach (DE); Bernhard ENDRES, Nabburg (DE)

(21) Appl. No.: 19/305,428

(22) Filed: Aug. 20, 2025

(30) Foreign Application Priority Data
Aug. 30, 2024 (DE) 102024124875.0

(51) Int. Cl. G01R 33/09

(52) U.S. Cl. CPC G01R 33/098

(57) ABSTRACT

A magnetoresistive sensor includes a layer stack containing at least one reference layer having a reference magnetization perpendicular to the plane of the layer stack and at least one free layer having a vortex magnetization. The magnetoresistive sensor furthermore includes at least one soft-magnetic shield arranged adjacent to the layer stack and configured to reduce an influence of an external magnetic field along a shielding axis on the free layer.

### CROSS-REFERENCE TO RELATED APPLICATION

This application claims priority to Germany Patent Application No. 102024124875.0 filed on Aug. 30, 2024, the content of which is incorporated by reference herein in its entirety.

### TECHNICAL FIELD

The present disclosure relates to magnetoresistive sensors capable of measuring and detecting external out-of-plane (OOP) magnetic fields.

### BACKGROUND

Magnetoresistive sensors, in particular those based on the principle of tunneling magnetoresistance (TMR), are increasingly being used in various industrial and commercial applications, including automotive engineering, medical technology and consumer electronics. These sensors offer high sensitivity and accuracy in terms of magnetic field detection, making them a preferred choice in demanding measurement environments.

A typical TMR sensor comprises a layer stack, which in turn comprises various magnetic and non-magnetic layers. This layer stack generally comprises a reference layer and a free layer (sensor layer), which are separated from one another by a non-magnetic tunnel barrier. The magnetization of the reference layer is in this case fixed and oriented in a certain direction, while the magnetization of the free layer may be influenced by external magnetic fields, thereby changing the electrical resistance of the TMR sensor.

Magnetoresistive sensors having a reference magnetization that runs perpendicular to the plane of the layer stack, also known as out-of-plane (OOP) magnetization, are known. At the same time, the free layer may be configured so as to have a vortex magnetization, in which magnetization vectors run in a circular arrangement within the plane, and a central area exists in which the magnetization runs perpendicular to the plane. This special arrangement of the magnetization in the free layer makes it possible to control the interactions with external magnetic fields in a targeted manner and thereby to achieve high sensitivity and stability of the sensor.

One problem that occurs with magnetoresistive sensors having the described magnetization arrangement concerns sensitivity to external magnetic fields running parallel to the plane of the layer stack, also known as in-plane (IP) cross magnetic fields. Such external cross magnetic fields may destabilize the magnetization of the free layer, which may lead to unwanted measurement inaccuracies. This may significantly affect the performance of the sensor, in particular when measuring weak magnetic fields or in environments containing strong interfering fields.

One challenge is thus to reduce this sensitivity without affecting the underlying structure of the layer stack or the advantages of OOP and vortex magnetization.

### SUMMARY

This is achieved by way of magnetoresistive sensors according to the attached claims.

According to a first aspect of the present disclosure, a magnetoresistive sensor is proposed. The magnetoresistive sensor includes a layer stack containing at least one reference layer having a magnetization perpendicular to the plane (out-of-plane, OOP) of the layer stack. The layer stack furthermore includes at least one free layer having a vortex magnetization. Vortex magnetization may be defined as a magnetization in a vortex arrangement, wherein magnetization vectors run in-plane and have a central area in which the magnetization runs perpendicular to the plane (OOP). The magnetoresistive sensor furthermore includes at least one soft-magnetic shield arranged adjacent to the layer stack and configured to reduce an influence of an external (in-plane, IP) magnetic field along a shielding axis on the free layer.

The proposed magnetoresistive sensor thus uses a combination of OOP reference layer and vortex magnetization in the free layer. The soft-magnetic shield, arranged adjacent to the layer stack, is used to reduce sensitivity of the sensor to external cross magnetic fields. One advantage of this arrangement is that it is able to increase the precision of the sensor by minimizing unwanted magnetic field influences, which is particularly important in applications requiring high measurement accuracy.

According to some example implementations, the soft-magnetic shield is configured to generate a magnetic opposing field in response to the external magnetic field. The generation of an opposing field by the soft-magnetic shield is based on intrinsic magnetic properties of soft-magnetic materials used. Soft-magnetic materials are distinguished by high magnetic permeability, which means that they are easily able to amplify and conduct external magnetic fields. When an external magnetic field impinges on the soft-magnetic shield, the high permeability of the material causes the field to penetrate into the material and align along the preferred magnetic axes within the shield. This orientation generates, within the shield, an internal magnetic field capable of forming an opposing field to the incident external field. The generated opposing field counteracts the external magnetic field, which leads to the external field being attenuated or neutralized in the immediate environment of the sensor. This interaction maintains the stability of the magnetization of the free layer of the sensor and reduces unwanted effects that could be caused by external magnetic fields. The opposing field is in this case controlled by the spatial arrangement and the material properties of the shield, such that it reacts specifically to the external field and compensates therefor in the desired way. This mechanism helps to minimize the influence of interfering fields on the sensor and increase its measurement accuracy.

According to some example implementations, the shield is arranged laterally adjacent to the layer stack. The lateral arrangement of the shield enables targeted shielding of cross magnetic fields running parallel to the layer plane. One advantage of this arrangement is that it provides an effective shield without significantly increasing the footprint of the sensor, resulting in a compact design.

According to some example implementations, the shield is arranged above or below the layer stack. The placement of the shield above or below the layer stack enables flexible integration into the sensor structure. One advantage of this arrangement is that it is able to facilitate adaptation of the shield to specific application requirements.

According to some example implementations, the extent of the shield perpendicular to the shielding axis is greater than it is parallel to the shielding axis. A greater extent of the shield perpendicular to the shielding axis increases the linear shielding area for external cross magnetic fields. One advantage of this implementation is that it offers an improved shielding effect in the case of large magnetic fields and also increases the area available for field compensation.

According to some example implementations, the extent of the shield perpendicular to the shielding axis is at least 4 times greater than the extent of the shield parallel to the shielding axis. The ratio of at least 4:1:1, 10:1:1 or 100:1:1 between the perpendicular and parallel extents makes it possible to achieve optimum shielding performance. One advantage of this geometry is that it is able to ensure particularly effective suppression of interfering fields, which is able to further improve the sensitivity of the sensor.

According to some example implementations, a material of the shield includes a nickel-iron alloy, a cobalt-iron alloy, a cobalt-nickel alloy, or an iron-silicon alloy. These materials are known for their excellent soft-magnetic properties, making them ideal for use in shields. One advantage of using these alloys is that they offer high magnetic permeability and low coercive field strength, thereby allowing the shield to be efficient and have a fast reaction time.

According to some example implementations, the saturation magnetization of a material of the shield is in a range of 1-1.5 Tesla. Saturation magnetization in this range makes it possible to ensure that the shield has sufficient magnetic strength to effectively compensate for external cross magnetic fields. One advantage of this material property is that it enables high efficiency of the shield, even in the case of strong external cross magnetic fields.

According to some example implementations, the at least one shield is cuboidal. The cuboidal design of the shield makes it possible to facilitate production and integration into the sensor structure. One advantage of this shape is that it enables uniform and stable field distribution, which may increase the efficiency of the shield.

According to some example implementations, the shield has a first soft-magnetic bar and a second soft-magnetic bar that intersect at right angles. The arrangement of two bars at right angles makes it possible to achieve shielding in two directions. One advantage of this configuration is that it is able to effectively reduce in-plane magnetic fields both in the x-direction and in the y-direction, increasing the versatility of the sensor.

According to some example implementations, the shield has a plurality of soft-magnetic bars arranged in parallel, wherein the bars each have a longitudinal axis running perpendicular or parallel to the shielding axis. The parallel arrangement of multiple bars offers an extended shielding surface that increases magnetic field suppression efficiency. One advantage of this arrangement is that it enables uniform shielding over a larger area, which is particularly advantageous for applications involving larger-area sensors.

According to some example implementations, a distance between adjacent soft-magnetic bars is greater than 5 μm. A greater distance between the (soft-magnetic) bars reduces possible interference between the shielding elements and ensures more effective field compensation by forming a homogeneous opposing field. One advantage of this geometry is that it optimizes shielding performance by minimizing unwanted cross magnetic fields.

According to some example implementations, a shortest distance between the layer stack and the shield is in a range of 2-3 μm. Such a distance between the layer stack and the shield may ensure effective cross-field compensation without affecting the sensor function. One advantage of this arrangement is that it enables high shielding performance with a small footprint, which contributes to the compactness of the sensor.

According to some example implementations, the layer stack includes a TMR layer stack. A TMR layer stack, combined with a vortex-magnetized free layer, offers excellent magnetoresistive properties, increasing the sensitivity and accuracy of the sensor. One advantage of this implementation is that it enables high resolution and precision when measuring external OOP magnetic fields, which is advantageous for numerous applications.

According to some example implementations, the layer stack and the at least one shield are arranged on a common die (chip). The common arrangement on a semiconductor die facilitates the integration and miniaturization of the sensor. One advantage of this arrangement is that it is able to reduce production costs and increase the compactness of the overall system, which is paramount for modern electronics applications.

According to a further aspect of the present disclosure, a bridge circuit having a plurality of magnetoresistive sensors according to one of the preceding example implementations is proposed. Integration into a bridge circuit enables for example more precise measurement of magnetic fields through differential measurement. One advantage of this implementation is that it is able to further increase the accuracy and sensitivity of the sensor system, which is particularly useful in demanding measurement environments.

According to some example implementations, a cross field-insensitive working range of a magnetic vortex sensor carrying out measurements out-of-plane may be extended far beyond what is intrinsically possible by adding adjacent cross field-counteracting soft-magnetic structures, referred to as “shields”. The shield reduces the effective parasitic cross fields, thereby preserving the vortex structure of the free layer (and thus expanding the operating range), while not affecting the field components along the sensitive direction out of plane.

### BRIEF DESCRIPTION OF THE DRAWINGS

Some examples of devices and/or methods are explained in more detail below merely by way of example with reference to the accompanying figures. In the figures:

FIG. 1 shows one example of a layer stack of a magnetoresistive sensor element according to one implementation;

FIG. 2 shows a micromagnetic simulation of a disk with a diameter of 0.25 μm, with homogeneous magnetization on the left-hand side and a vortex state on the right-hand side;

FIG. 3 shows out-of-plane (OOP) and in-plane (IP) hysteresis of a magnetic vortex with a diameter of 128 nm and a height of 64 nm; the figure illustrates the reaction of the vortex to external magnetic fields;

FIG. 4 shows an out-of-plane (OOP) magnetization, which is barely influenced by in-plane cross fields in a stable working range, wherein significant effects occur only above an annihilation field;

FIG. 5 shows a magnetoresistive sensor having a laterally adjacent shield, according to one example implementation;

FIG. 6 shows a magnetoresistive sensor having a laterally and upwardly adjacent shield, according to a further example implementation;

FIG. 7 shows a magnetoresistive sensor having a layer stack between two shielding bars, according to a further example implementation; and

FIG. 8 shows a magnetoresistive sensor having a TMR layer stack under a shielding bar, according to a further example implementation;

FIG. 9 shows a perspective bridge circuit containing a plurality of magnetoresistive sensors under a grid of shielding bars; and

FIG. 10 shows a plan view of the bridge circuit of FIG. 9.

### DETAILED DESCRIPTION

Some examples are now described in more detail with reference to the accompanying figures. However, further possible examples are not restricted to the features of these implementations that are described in detail. These may include modifications of the features, as well as equivalents and alternatives to the features. Furthermore, the terminology used herein to describe specific examples should not be restrictive for further possible examples.

The same or similar reference signs relate throughout the description of the figures to the same or similar elements or features, which may each be implemented identically or else in a modified form, while providing the same or a similar function. In the figures, the thicknesses of lines, layers and/or regions may also be exaggerated for clarification.

When two elements A and B are combined using an “or”, this should be understood as meaning that all possible combinations are disclosed, that is to say only A, only B, and also A and B, unless expressly defined otherwise in the individual case. “At least one of A and B” or “A and/or B” may be used as alternative wording for the same combinations. This applies equivalently to combinations of more than two elements.

If a singular form, for example “a, an” and “the”, is used, and the use of only a single element is neither explicitly nor implicitly defined as mandatory, other examples may also use multiple elements to implement the same function. When a function is described in the following as being implemented using multiple elements, further examples may implement the same function using a single element or a single processing entity. Furthermore, it goes without saying that the terms “comprises”, “comprising”, “has” and/or “having” when used describe the presence of the stated features, whole numbers, steps, operations, processes, elements, components and/or a group thereof, but do not thereby exclude the presence or the addition of one or more other features, whole numbers, steps, operations, processes, elements, components and/or a group thereof.

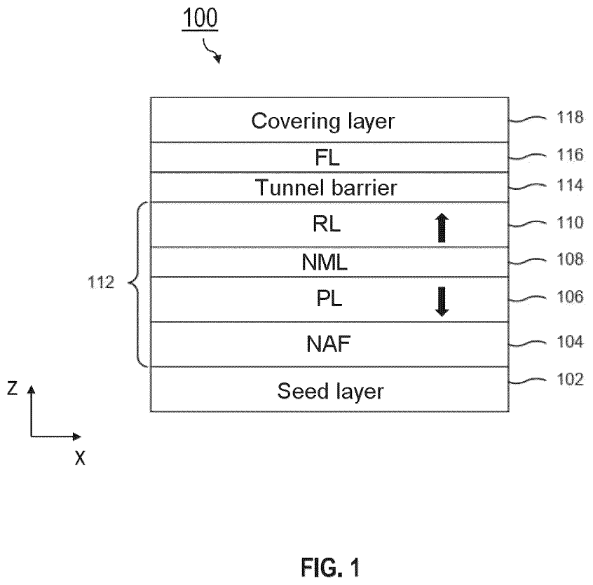

FIG. 1 shows one example of a layer stack of a magnetoresistive sensor element 100 according to one or more implementations.

The magnetoresistive sensor element 100 may be for example a TMR sensor element having a bottom-pinned spin-valve (BSV) configuration or a top-pinned spin-valve (TSV) configuration. In addition, the magnetoresistive sensor element 100 may be arranged on a semiconductor substrate (not illustrated) of a magnetoresistive sensor. When described in a Cartesian coordinate system with coordinate axes x, y and z that are perpendicular to one another in pairs, the layers of the layer stack extend laterally in an xy-plane spanned by the x-axis and y-axis. Lateral dimensions (for example lateral distances, lateral cross-sectional areas, lateral surfaces, lateral extents, lateral shifts etc.) may therefore relate to dimensions in the xy-plane and vertical dimensions may relate to dimensions in the z-direction, perpendicular to the xy-plane. The vertical extent of a layer in the z-direction may therefore be referred to as the layer thickness, for example.

The layer stack of the magnetoresistive sensor element 100 comprises at least one reference layer with a reference magnetization (for example a reference direction in the case of GMR or TMR technology). The reference magnetization is a magnetization direction that provides a sensor direction corresponding to a sensor axis of the magnetoresistive sensor element 100. The reference layer and consequently the reference magnetization define a sensor plane. The sensor plane may be defined by the xy-plane, for example. The x-direction and the y-direction may therefore be referred to as “in-plane” with respect to the sensor plane and the z-direction may be referred to as “out-of-plane” with respect to the sensor plane. Accordingly, in the case of a GMR sensor element or a TMR sensor element, the resistance of the magnetoresistive sensor element 100 is at a minimum if the magnetically free magnetization of a magnetically free layer points exactly in the same direction as the reference magnetization (for example the reference direction), and the resistance of the magnetoresistive sensor element 100 is at a maximum if the magnetically free magnetization of the magnetically free layer points exactly in the opposite direction to the reference magnetization. The orientation of the magnetically free magnetization of the magnetically free layer is variable when an external magnetic field is present. Therefore, the resistance of the magnetoresistive sensor element 100 may vary based on an influence of the external magnetic field on the magnetically free magnetization of the magnet-free layer.

From the bottom to the top, the magnetoresistive sensor element 100 may comprise an optional seed layer 102, which may be used to influence and/or optimize stack growth. In some implementations, the seed layer 102 may be composed of copper, tantalum, ruthenium or a combination thereof. In the example shown, an optional natural antiferromagnetic (NAF) layer 104 is formed on the seed layer 102 or is arranged elsewhere. The NAF layer 104 may consist of manganese nitride (MnN), platinum-manganese (PtMn), iridium-manganese (IrMn), nickel-manganese (NiMn) or the like. The layer thickness of the NAF may be in the range of 5 nm to 50 nm, for example. However, the magnetoresistive sensor element 100 may also make do without an NAF layer.

In addition, a pinned layer (PL) 106 may be formed on the NAF layer 104 or arranged elsewhere. The pinned layer 106 may consist of a ferromagnetic material, such as for example platinum-cobalt (Pt/Co), palladium-cobalt (Pd/Co) or nickel-cobalt (Ni/Co) multilayer systems, as well as cobalt-iron (CoFc) or cobalt-iron-boron (CoFeB) alloys. Contact between the NAF layer 104 and the pinned layer 106 may cause an effect that is known as the exchange bias effect and causes the magnetization of the pinned layer 106 to be oriented in a preferred direction (for example in the negative z-direction, as illustrated). The magnetization of the pinned layer 106 may be referred to as pinned magnetization. This pinned magnetization may be generated when producing the magnetoresistive sensor element 100 and may be permanently fixed.

The magnetoresistive sensor element 100 also comprises an non-magnetic layer (NML), which is referred to as a coupling intermediate layer 108. In one possible implementation, the coupling intermediate layer 108 may comprise, for example, ruthenium, iridium, tantalum, copper, copper alloys or similar materials. Other materials (for example paramagnets) are likewise possible. A magnetic (for example ferromagnetic) reference layer (RL) 110 may be formed on the coupling intermediate layer 108 or arranged elsewhere. The thickness of the pinned layer 106 and of the magnetic reference layer 110 may be in the range of 1 nm to 10 nm.

Accordingly, the coupling intermediate layer 108 may be arranged between the pinned layer 106 and the magnetic reference layer 110 in order to spatially separate the pinned layer 106 and the magnetic reference layer 110 in the vertical direction. In addition, the coupling intermediate layer 108 may provide intermediate layer exchange coupling (for example antiferromagnetic Ruderman-Kittel-Kasuya-Yosida (RKKY) coupling) between the pinned layer 106 and the magnetic reference layer 110 in order to form an artificial antiferromagnet. Consequently, a magnetization of the magnetic reference layer 110 may be aligned and kept in a direction that is antiparallel to or opposite the magnetization of the pinned layer 106 (for example in the positive z-direction, as illustrated). The magnetization of the magnetic reference layer 110 may be referred to as reference magnetization.

Since the NAF layer 104 is configured such that it aligns and fixes the magnetization of the pinned layer 106 in a particular direction and the coupling intermediate layer 108 is configured such that it aligns and fixes the magnetization of the magnetic reference layer 110 in an opposite direction, it may be the that the NAF layer 104 is configured to keep the magnetization of the pinned layer 106 (for example a fixed magnetization) in a first magnetic alignment and to keep the magnetization of the magnetic reference layer 110 (for example a fixed reference magnetization) in a second magnetic alignment. The magnetic reference layer 110 may thereby have a linear magnetization pattern in the z-direction if the pinned layer 106 has a linear magnetization pattern in an antiparallel direction. Therefore, the NAF layer 104, the pinned layer 106, the coupling intermediate layer 108 and the magnetic reference layer 110 form a magnetic reference layer system 112 of the magnetoresistive sensor element 100.

The magnetoresistive sensor element 100 additionally comprises a barrier layer 114 (for example a tunnel barrier) arranged vertically between the reference layer system 112 and a magnet-free layer 116. The barrier layer 114 may be formed, for example, on the magnetic reference layer 110 of the reference layer system 112 or arranged elsewhere, and the magnetically free layer 116 may be formed on the barrier layer 114 or arranged elsewhere.

The barrier layer 114 may consist of a non-magnetic material. In some implementations, the barrier layer 114 may be an electrically insulating tunnel barrier layer. For example, the barrier layer 114 may be a tunnel barrier layer used to generate a TMR effect. The barrier layer 114 may consist of magnesium oxide (MgO), aluminum oxide (Al2O3), magnesium aluminum oxide (MgAlOx) or another material with similar properties.

The material of the magnetically free layer 116 be an alloy of a ferromagnetic material, such as for example CoFe, CoFeB or NiFe. The magnetostriction constant of the magnetically free layer 116 may be adjusted using the iron content. In addition, the magnetically free layer 116 may contain platinum-cobalt (Pt/Co), palladium-cobalt (Pd/Co) or nickel-cobalt (Ni/Co) multilayers in order to further optimize the magnetic properties. The magnetically free layer 116 has a magnetically free magnetization that is variable when an external magnetic field is present. Therefore, the magnetically free layer 116 may be referred to as a sensor layer since changes in the magnetically free magnetization are used to determine a measurement variable. In addition, the magnetically free magnetization has a magnetic standard alignment (such as for example a vortex magnetization) in a basic state. The basic state is a state in which the influence of the external magnetic field on the magnetically free layer 116 is not present or is negligibly small. In some implementations, the magnetoresistive sensor element 100 may comprise a magnetically free system containing a multiplicity of layers (for example two or more magnetically free layers) that act in combination as a magnetically free layer. In this case, the magnetically free layers of the magnetically free system are magnetically coupled to one another. The magnetically free system may therefore act as a magnetically free layer, but may also consist of a plurality of layers. The magnetically free system has a magnetically free magnetization, wherein the magnetically free magnetization is variable when the external magnetic field is present.

A covering layer 118, for example made of tantalum (Ta), tantalum nitride (TaN), ruthenium (Ru), titanium (Ti), titanium nitride (TiN), platinum (Pt) or the like, may be formed on the magnetically free layer 116 or arranged elsewhere in order to form an upper layer of the magnetoresistive sensor element 100.

The seed layer 102 may be used as a lower electrode or may establish electrical contact with a lower electrode (not illustrated) of the magnetoresistive sensor element 100. The covering layer 118 may establish electrical contact with an upper electrode (not illustrated) of the magnetoresistive sensor element 100. The barrier layer 114 may be configured such that electrons are able to tunnel between the reference layer system 112 and the magnetically free layer 116 if a bias voltage is applied to the electrodes of the magnetoresistive sensor element 100 (not illustrated) in order to generate a magnetoresistance effect (for example a TMR effect).

As mentioned above, FIG. 1 is used only as an example of a TMR sensor element. Other examples may differ from the description in FIG. 1. The number and arrangement of the components shown in FIG. 1 is an example. In practice, the TMR sensor element 100 may contain additional elements or layers, fewer elements, different elements or differently arranged elements than those shown in FIG. 1.

In order to realize a linear out-of-plane (OOP) magnetic field sensor based on the TMR effect, a magnetically free layer 116 (sensor layer) with linear OOP behavior is required in addition to an OOP reference system 112. Homogeneously magnetized ferromagnets with an in-plane (IP) axis meet this requirement. However, at a given time, the magnetization direction directly depends on a vector sum of the OOP and IP field components, resulting in high cross-field sensitivity when used for OOP field measurement. In addition, cross-field sensitivity scales proportionally to OOP sensitivity, which may represent a significant constraint for OOP field measurement.

An in-plane (IP) cross magnetic field is a magnetic field that runs parallel to the plane of the layer stack of a magnetoresistive sensor, that is to say for example in the plane defined by the x-axis and y-axis. The term “cross magnetic field” refers to the fact that this magnetic field may have an interfering effect on the measurements carried out using the sensor, in particular if the sensor is configured to detect magnetic fields that run perpendicular to the layer stack plane (out-of-plane, OOP, along the z-axis). These IP cross magnetic fields may influence the magnetization of the free layer in the sensor and thereby cause measurement inaccuracies, which is why they must be compensated for as far as possible in the design of the sensor.

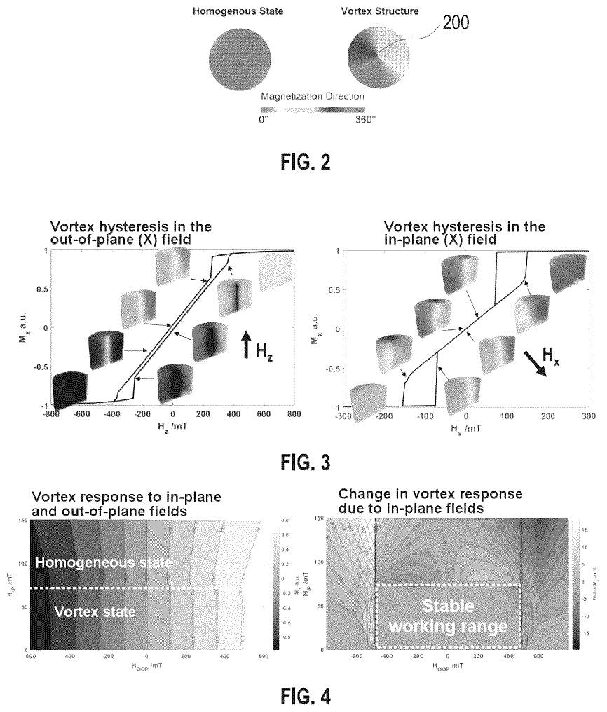

One solution for minimizing cross-field sensitivity is the use of a magnetically free layer 116 with a vortex basic state instead of a homogeneous magnetization, as illustrated in FIG. 2. A vortex basic state in the magnetically free layer 116 describes a special arrangement of the magnetization in which the magnetization vectors are arranged in a circular pattern. In this state, the magnetizations of the individual areas of the layer run mainly in the plane of the layer and in so doing form a spiral-shaped or vortex-shaped structure similar to a vortex. At the center of this vortex, the magnetization may be aligned perpendicular to the layer plane, creating a stable magnetic state that is less sensitive to external magnetic fields running transverse to the layer. In a vortex state, the force of the external cross field (also called Zeeman energy) is compensated for by the magnetically free layer 116 by virtue of the vortex core being deflected perpendicular to the field direction, as a result of which the external field is absorbed without any noteworthy effect on the sensitive component of the magnetization outside the plane. However, this vortex state is not stable in the case of higher cross magnetic fields, as the vortex state collapses above a certain field amplitude and returns to homogeneous magnetization with high cross-field sensitivity.

Vortex stability scales approximately proportionally to t/d (thickness divided by diameter) and is also proportional to the saturation magnetization Ms of the material used for the magnetically free layer 116. The intrinsic stabilization of the vortex configuration therefore requires materials that are unfavorable for OOP sensors (high saturation magnetization), and also structure sizes well below 0.5 μm in combination with layer thicknesses >100 nm.

A magnetic vortex is a unique spin configuration in which the magnetization vectors wind around a vortex core 200 and create a vortex-like pattern (see FIG. 2). This vortex core 200 is an area with a high energy density due to the non-aligned magnetic moments, and typically has a polarity in which the magnetic moments point either up or down out of the plane of the magnetically free layer 116.

In the presence of external magnetic fields, the vortex exhibits pronounced hysteresis behavior. When a vortex is exposed to external magnetic fields in a magnetically free layer, it exhibits a characteristic hysteresis behavior. This means that the reaction of the vortex to the applied magnetic field is not linear, but depends on the history of the applied magnetic field. Specifically, the vortex changes its position and magnetization structure when the external field is applied or modified. However, these changes partially persist even after the external magnetic field has been removed. The hysteresis behavior is shown by the fact that the magnetization structure of the vortex does not return immediately or completely to its original state, but remains in a modified state. It is only by applying a counteracting magnetic field or through other changes to the environmental conditions that the vortex is able to gradually return to its original state. This hysteresis behavior is typical of magnetic systems and shows that the magnetization of the vortex depends not only on the current strength and direction of the external field, but also on the previous magnetization states to which the system was exposed. This leads to a complex interaction between the vortex and the external magnetic fields, which influences the stability and dynamics of the magnetic system. It is possible to simulate this behavior using micromagnetic finite-difference simulations. If considering the simulated vortex hysteresis curves illustrated in FIG. 3, then both the out-of-plane reaction (FIG. 3 (a)) and the in-plane reaction to the magnetic field (FIG. 3 (b)) appear to be similar in terms of quality. However, if considering the actual spin structures, significant differences arise.

When an in-plane magnetic field is applied to a magnetic vortex, the field interacts with the chirality of the vortex, that is to say the direction of rotation of the magnetization vectors around the core 200. This interaction causes the vortex to experience a force that makes it move or circle in the plane of the magnetically free layer 116. The field deforms the vortex structure and causes the core 200 to be deflected perpendicular to the external field direction, which ultimately leads to the vortex being destroyed (since the core 200 is “squeezed out” of the structure) when the field is strong enough (see FIG. 3 (b)). If the field is lowered, the vortex will seed again with a given field, as it resembles the state of equilibrium of the magnet.

In contrast, an out-of-plane magnetic field interacts directly with the polarity of the vortex core 200. An OOP field tends to align the magnetic moments vertically, which may either stabilize or destabilize the core 200 depending on the field direction in relation to the polarity of the core 200. When the field is opposed to the polarity of the core 200, the vortex core 200 is compressed, figuratively speaking, by virtue of the magnetization of the free layer 116 slowly aligning counter to the polarization direction of the vortex core 200 and ultimately destroying it in the case of high fields. If, on the other hand, the field aligns according to the polarity of the vortex core 200, the magnetization of the free layer 116 aligns along the polarization direction, and the vortex core 200 thus expands alongside, which ultimately also leads to a transition to a one-dimensional state, as illustrated in FIG. 3 (a). When the OOP field is lowered, seeding occurs again.

A TMR sensor having an OOP reference system 112 reacts only to changes in the OOP component of the magnetization. As long as the vortex state is intact, IP fields are compensated for by the deflection of the vortex core 200 as described above. The effect on OOP magnetization is minimal. This becomes clear in FIG. 4, which shows contour diagrams of the OOP component influenced by OOP and IP fields. The diagrams illustrate results of a series of micromagnetic simulations for a vortex with a diameter of 256 nm and a height of 64 nm, which has a saturation magnetization of 1 T. FIG. 4 (on the left) shows a contour diagram of the out-of-plane (OOP) component of the magnetization (Mz). It illustrates the OOP vortex reaction in the presence of out-of-plane (x-axis) and in-plane (y-axis) fields. In the case of low IP fields, the OOP reaction is barely influenced. It is only above the annihilation field (around 75 mT) that the magnetization is influenced significantly by the IP cross field. FIG. 4 (on the right) indicates the effect of the in-plane cross field on the OOP component as a percentage. In the area marked as a stable working range, the influence of the cross field is less than 0.5% (simulation parameters: diameter=256 nm, height=64 nm, saturation magnetization (Ms)=1 T, cell size=2 nm).

The effective “immunity” to IP cross fields makes the vortex structure an ideal magnetization state for measuring external OOP fields. However, this is only the case as long as the vortex structure is able to be protected from being annihilated by potentially significant IP cross fields. Annihilation in this connection means the destruction or dissolution of the vortex structure. If the vortex structure is exposed to potentially significant IP cross fields that are sufficiently strong, this may cause the vortex to become unstable and lose its characteristic vortex shape. Reference is made in that case to annihilation of the vortex. This annihilation would cause the vortex to lose its immunity to IP cross fields and no longer be capable of accurately measuring OOP fields.

The field of use of a vortex disk is defined primarily by the saturation magnetization (Ms) of the material used and the disk geometry. The annihilation fields scale linearly with Ms and are also directly proportional to the ratio of thickness and diameter. In other words, increasing stability requires higher Ms-materials, further scaling of the components or larger layer thicknesses. Both scaling the components and increasing the layer thickness entail considerable additional costs. Large Ms-materials, on the other hand, adversely affect the sensitivity of the component, since the OOP reaction of the vortex scales inversely proportionally to Ms.

The solution proposed here concerning “immunity” to IP cross fields makes it possible to extend an operational cross-field range of an OOP magnetoresistive sensor with a free layer with vortex magnetization by reducing effective in-plane cross-field amplitudes acting on the vortex during operation. To achieve this, use is made of counteracting stray fields emanating from adjacent soft-magnetic structures in the micrometer range. These “shields”, as they are known, exhibit linear M-H behavior depending on their geometry and enable constant shielding factors over a wide field range. The shields may be placed at a small distance above and/or below the magnetoresistive sensors.

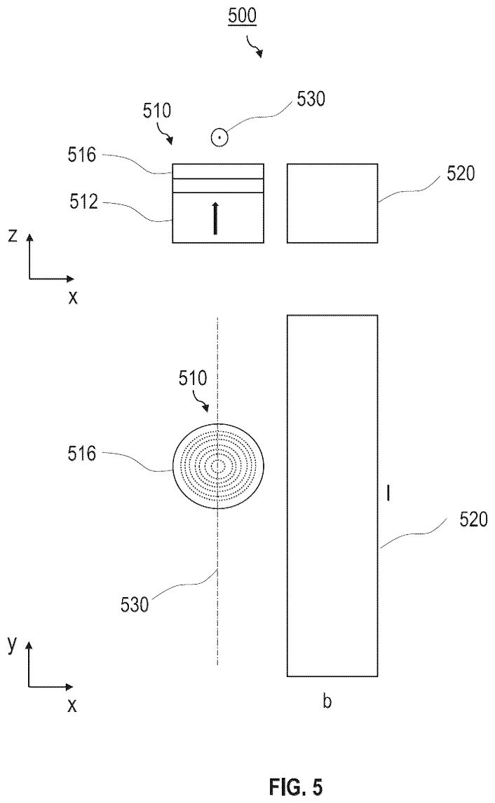

FIG. 5 schematically shows a magnetoresistive sensor 500 according to one example implementation of the present disclosure. While the upper part of FIG. 5 shows a schematic side view of the magnetoresistive sensor 500, the lower part of FIG. 5 illustrates a schematic plan view.

The magnetoresistive sensor 500 contains a layer stack 510, which may be similar to the magnetic tunnel junction (MTJ) from FIG. 1. The tunnel contact 510 contains at least one reference layer 512 that is magnetized such that its magnetization runs perpendicular to the plane of the layer stack (out-of-plane, OOP). In addition, the layer stack 510 contains a free layer 516 the magnetization of which is arranged in a vortex-shaped pattern, known as vortex magnetization. The sensor 500 is furthermore equipped with at least one soft-magnetic shield 520, which is located in the immediate vicinity of the layer stack 510. The shield 520 is configured to reduce the effects of external magnetic fields running parallel to the plane of the layer stack (in-plane, IP) on the free layer 516. This takes place along a direction called the IP shielding axis 530.

The term “immediate vicinity” refers here to a positioning in which the shield is brought as close as possible to the layer stack in order to achieve an optimum shielding effect. This proximity enables the shield to generate a strong opposing field that compensates for interfering external magnetic fields before they reach the sensitive layers of the layer stack. At the same time, the shield is close enough to ensure effective field compensation, but far enough away not to affect the normal operation of the layer stack. According to some example implementations, a shortest distance between the layer stack 510 and the shield 520 is in a range of 2-3 μm. The “shortest distance” refers to the smallest distance between nearest points of the layer stack 510 and of the shield 520.

In order to minimize external interference, especially magnetic fields running parallel to the plane of the sensor, a soft-magnetic shield 520 is thus used. This shield 520 is able to generate an opposing field that neutralizes the interfering influences and is thus able to improve the functionality and accuracy of the sensor 500. The IP shielding axis 530 describes a direction along which the shield is effective and reduces the interfering cross field.

The shield 520 may be made for example of a nickel-iron alloy, a cobalt-iron alloy, a cobalt-nickel alloy, or an iron-silicon alloy. These alloys have excellent soft-magnetic properties. They are easy to magnetize and demagnetize, making them ideal for applications in magnetic field shields. Nickel-iron (for example permalloy) is known for its high magnetic permeability and low coercive field strength, which means that it is able to conduct magnetic fields very well without retaining permanent magnetization itself. This means that the shield 520 is able to effectively neutralize external magnetic fields and at the same time maintain its original magnetic properties. A cobalt-iron alloy offers high saturation magnetization, making it particularly suitable for shielding strong magnetic fields. A cobalt-nickel alloy combines the advantageous properties of cobalt and nickel to offer a balanced blend of high saturation magnetization and good magnetic permeability. An iron-silicon alloy is popular due to its good magnetic properties and its resistance to magnetization losses. It is often used in applications requiring durable and reliable shielding. The choice of the specific alloy depends on the requirements of the application, including the strength of the external magnetic fields to be expected and the desired mechanical properties of the shield.

In the implementation illustrated in FIG. 5, the soft-magnetic shield 520 is arranged laterally adjacent to the layer stack. In other words, the soft-magnetic shield 520 may be arranged laterally next to the tunnel contact 510. The laterally arranged shield 520, in response to an external IP field, generates a magnetic IP opposing field that reduces the influence of the external IP field. This opposing field also acts at least partially on the nearby layer stack 510 and neutralizes the interfering external IP field. This preserves the stability of the vortex magnetization in the free layer 516, resulting in improved accuracy and sensitivity of the sensor 500.

The soft-magnetic shielding 520 may for example be cuboidal. “Cuboidal” means that the shield 520 has the geometric shape of a cuboid, which describes a three-dimensional figure with six rectangular faces. Each of these faces is a rectangle, and the opposing faces of a cuboid are equal in size and parallel to one another. This shape makes it easy to produce the shield 520 and integrate it into the sensor 500, since it has clear and defined dimensions along its length l, width b and height h. The cuboidal shape additionally offers a uniform distribution of magnetic properties, which is important for effective shielding of magnetic fields.

The cuboidal shield 520 has an extent (length) l in the direction of the shielding axis 530 and an extent (width) b perpendicular to the shielding axis 530. The extent l in the direction of the shielding axis may be greater than the extent b perpendicular to the shielding axis 530. The extent l in the direction of the shielding axis may in particular be 4 times, 10 times or 100 times greater than the extent b perpendicular to the shielding axis 530.

In addition to the cuboidal design of the shield 520, other geometries having similar aspect ratios are also conceivable. Another possibility would be an elliptical plate, in which the main axis of the ellipse runs in the direction of the shielding axis 530 and is significantly longer than the secondary axis perpendicular to the shielding axis. The proportions described ensure that the shield 520 covers a larger area in the direction of the shielding axis 530, which may increase shielding efficiency. A larger extent in the direction of the shielding axis here enables more effective compensation of the external magnetic fields, since it offers a larger area that is able to generate the opposing field.

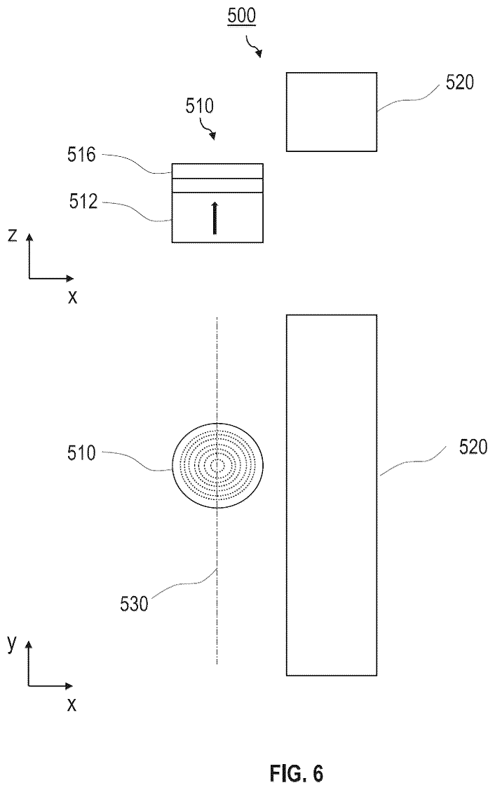

In the implementation illustrated in FIG. 6, the soft-magnetic shield 520 is arranged both laterally adjacent to the layer stack 510 and above the layer stack 510. In other words, the soft-magnetic shield 520 is positioned here both laterally next to the layer stack 510 and above the layer stack 510. It will be immediately obvious that the soft-magnetic shield 520 could also be positioned directly above the layer stack 510, that is to say without a lateral offset. Similarly, the soft-magnetic shield 520 could also be positioned both laterally next to the layer stack 510 and below the layer stack 510. The soft-magnetic shield 520 could also be positioned directly below the layer stack 510, that is to say without a lateral offset. An accurate positioning of the shield 520 relative to the layer stack 510 may depend on factors such as for example the geometry of the shield 520 and/or a desired shielding axis 530.

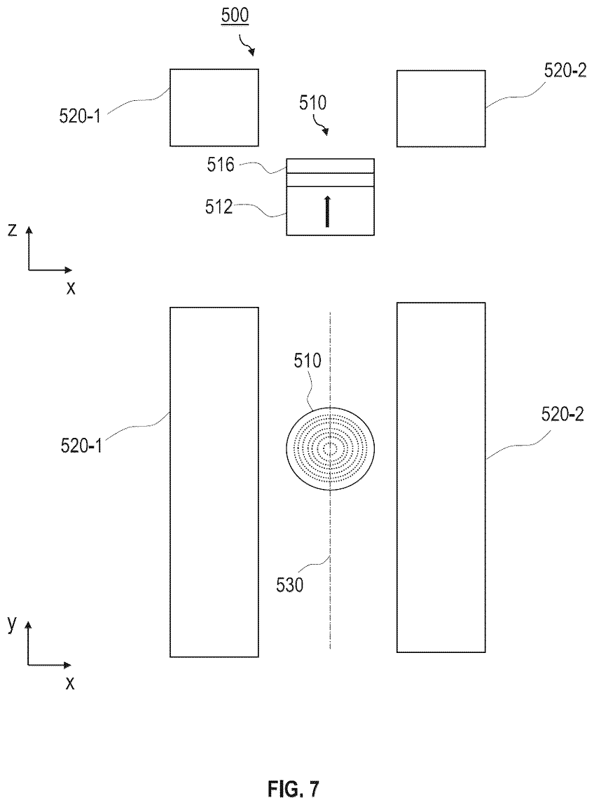

In the implementation illustrated in FIG. 7, the shield has a first soft-magnetic bar (cuboid) 520-1 and a second soft-magnetic bar (cuboid) 520-2 that run parallel to one another and perpendicular to the IP shielding axis 530. In the implementation illustrated in FIG. 7, the soft-magnetic bars 520-1, 520-2 are positioned above the layer stack 510 in the z-direction. The layer stack 510 is located between the soft-magnetic bars 520-1, 520-2 in the x-direction. The soft-magnetic bars 520-1 and 520-2 are thus located vertically above the layer stack 510, while the layer stack 510 is arranged between the two bars 520-1, 520-2 in the x-direction, that is to say horizontally. It will be immediately obvious that the soft-magnetic bars 520-1 and 520-2 could also be arranged below the layer stack 510.

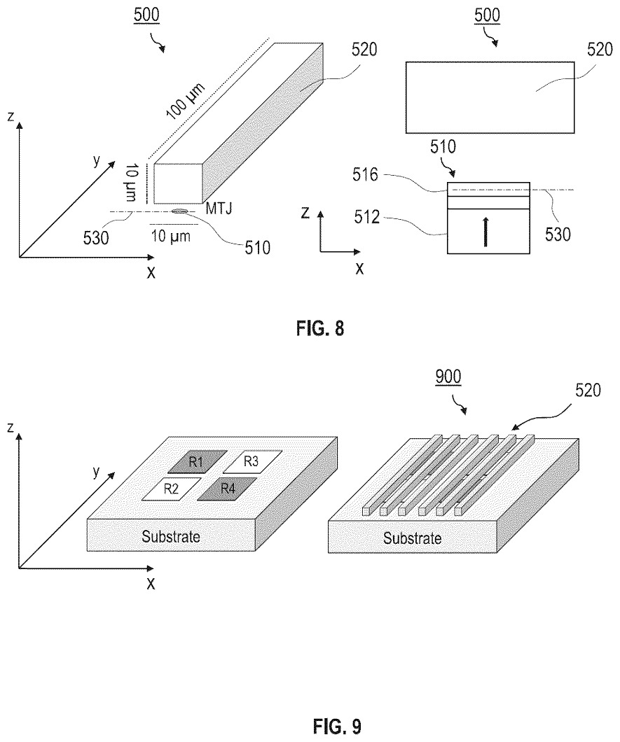

FIG. 8 shows a schematic perspective illustration of a magnetoresistive sensor 500, in which a soft-magnetic shield 520 is located above the TMR layer stack 510 in the z-direction. A distance is in the range of 0.5-3 μm. The cuboidal shield 520 here has an extent (width) b in the direction (x-direction) of the shielding axis 530 and an extent (length) l perpendicular (y-direction) to the shielding axis 530. The extent l perpendicular to the shielding axis 530 may be greater than the extent b in the direction of the shielding axis 530. In particular, the extent I perpendicular to the shielding axis may be 4 times, 10 times or 100 times greater than the extent b in the direction of the shielding axis 530. The shield 120 here has an example extent of 100 μm along the y-axis and of 10 μm along the x-axis. Here, the extent of the shield 520 perpendicular to the shielding axis 530 is thus 10 times greater than the extent of the shield 520 parallel to the shielding axis 530.

In addition to the cuboidal design of the shield 520, other geometries having similar aspect ratios are also conceivable. Another possibility would be an elliptical plate, in which the main axis of the ellipse runs perpendicular to the shielding axis 530 and is significantly longer than the secondary axis along the shielding axis.

FIG. 9 shows a comparison of two configurations of a chip 900 that works with TMR resistors R1, R2, R3, R4. The TMR resistors R1, R2, R3 and R4 together form a bridge circuit. In the bridge circuit, the resistors are arranged such that they modify the output voltage depending on external magnetic OOP fields acting on them. On the left, the chip is illustrated without a soft-magnetic shield while exposed to external IP cross fields with a strength of 400 mT. On the right, the same chip 900 is illustrated, but this time with multiple soft-magnetic shielding bars 520 arranged in parallel and above the bridge circuit consisting of R1, R2, R3, R4. These bars are used to reduce the effects of the IP cross fields by generating an opposing field that neutralizes the interfering magnetic fields.

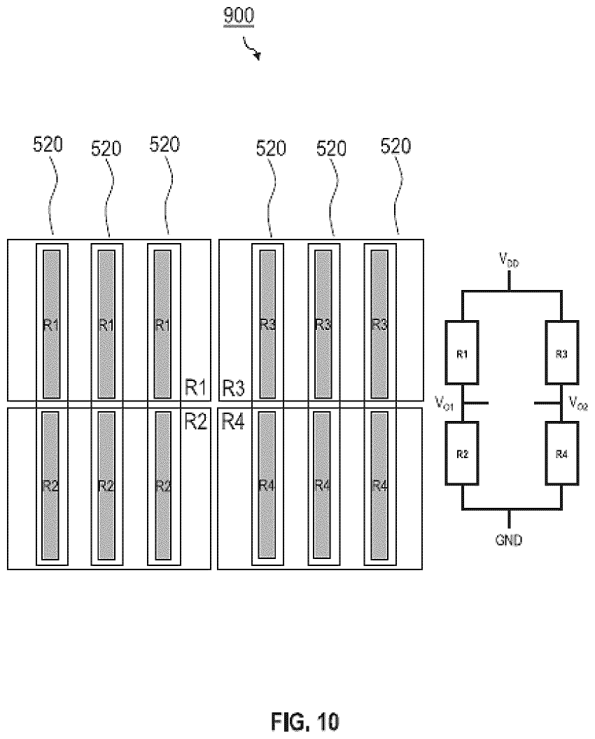

FIG. 10 shows a plan view of the bridge circuit from FIG. 9, with the four TMR resistors R1, R2, R3 and R4, which are integrated together on the chip 900. Each of the TMR resistors (R1, R2, R3 and R4) is formed by a plurality of tunnel contacts 510, which are integrated within a respective resistor area on the chip. These tunnel contacts 510 comprise a layer stack, which is typically formed of multiple magnetic and non-magnetic layers. The layer stack contains a free layer 516 and a reference layer 512 that are separated by a thin insulating layer. The tunnel contacts 510 within each resistor are arranged such that they, as a whole, determine the respective electrical resistance. The number of tunnel contacts and their specific alignment determine the sensitivity of the resistor to external magnetic fields.

Each resistor (R1, R2, R3, R4) of the bridge circuit is covered by multiple soft-magnetic shields 520 that run parallel to one another and are illustrated as rectangular structures. These shields are used to protect the resistors R1, R2, R3 and R4 from interfering IP magnetic fields by generating an opposing field that neutralizes unwanted external fields. A distance that corresponds approximately to the thickness of the shields themselves (for example 10 μm) is maintained between the individual soft-magnetic shields 520. This uniformity in terms of distance and thickness is able to ensure uniform and effective shielding.

The right-hand side of FIG. 10 illustrates a schematic circuit diagram of the bridge circuit, showing the electrical connection of the four TMR resistors R1, R2, R3 and R4. The resistors R1, R2, R3 and R4 are connected to form a Wheatstone bridge, wherein R1 and R2, along with R3 and R4, are each connected in series.

Example implementations of the present disclosure make it possible to extend the operational cross-field range of an OOP TMR sensor with a vortex sensor layer by reducing the effective in-plane cross-field amplitudes acting on the vortex during operation. To achieve this, use is made of counteracting stray fields emanating from adjacent soft-magnetic structures in the micrometer range. These shields exhibit linear M-H behavior depending on their geometry and enable constant shielding factors over a wide field range. The shields 520 may be placed at a small distance above and/or below the magnetic tunnel contacts.

Suitable shielding materials are soft-magnetic alloys such as NiFe, with a saturation magnetization between 1 and 1.3 Tesla. The saturation field (the field above which the magnet is in saturation and additional shielding is no longer possible) may then be approximated along the shielding axis 530 by the product of Ms and the demagnetization factor, which depends on the shield geometry. This shape-dependent demagnetization factor is between 0 and 1. To maximize it and achieve large shielding areas, the extent of the shield, for example perpendicular to the shielding axis 530, should be significantly greater (ratio >4:1:1) than its extent along the shielding axis. With ratios of around 10:1:1, it is possible to achieve demagnetization factors of ˜0.4. Alternative soft-magnetic materials with different saturation magnetizations may likewise be used if the shape is adapted in line with an envisaged shielding area.

The shielding factor scales with the extent of the shield 520 along the shielding axis 530, and is therefore inversely proportional to the shielding range. Finite-element simulations of shields with linear ranges of up to 0.5 T indicate that constant shielding factors of up to ˜10 are possible in close proximity to the shield 520 (distance <1 μm). The shielding factor scales by 1 divided by the distance from the shield 520. Close integration is therefore necessary. With shielding factors of around ˜10 for IP cross fields of up to ˜0.5 T, it is possible to use vortex disks with intrinsic annihilation fields well below 100 mT and at the same time to cover an operating range of up to ˜+/−0.5 T.

The magnetic fields emanating from the shield 520 interact with adjacent shields 520. Simulations show that this “crosstalk” may significantly reduce the range of the shields, meaning that sufficient distances between shields 520 are required. The distances must therefore be optimized in order to achieve the best results with a minimum footprint.

As an alternative, multiple shields 520 may also be used around a TMR layer stack. Using a crossing bar approach, it is possible for example to shield against both cross-field directions (for example x-direction and y-direction) at the same time. In this case, the shield may thus have first soft-magnetic bars running in parallel (for example in the x-direction) and second soft-magnetic bars running in parallel (for example in the y-direction), wherein the first and second bars intersect at right angles.

A second vortex of similar size directly below the layer stack 510 may likewise shield IP cross fields, but only by a factor of 2 and only up to the annihilation field of the vortex shield. The shield 520 may therefore also be disk-shaped and have a vortex magnetization. In combination with the upper bar shields, this may help to keep the free layer 516 in the vortex state, further increasing a cross field-immune operating range or significantly increasing freedom for the layer stack 510 and the design. In addition, z-sensitivity may be increased by the linear amplification of the z-field by the vortex shield.

In summary, the present disclosure relates to a magnetoresistive sensor that is configured to measure external out-of-plane (OOP) magnetic fields while minimizing sensitivity to interfering in-plane (IP) magnetic fields. The sensor uses a combination of a reference layer with an OOP magnetization and a free layer with a vortex magnetization. A soft-magnetic shield is positioned in close proximity to the layer stack in order to reduce the influence of external IP magnetic fields by generating an opposing field. This preserves the stability of the vortex magnetization and increases the measurement accuracy of the sensor.

Example implementations comprise a specific choice of material for and geometry of the soft-magnetic shield. The shield consists of alloys such as nickel-iron or cobalt-iron and may be configured in the form of one or more cuboids, wherein the extent of the shield perpendicular to the shielding axis is greater than it is parallel thereto. The arrangement is able to maximize field compensation efficiency and ensure a uniform distribution of magnetic properties. In some variants, the shield is positioned laterally next to the layer stack or above/below the layer stack in order to offer flexible integration options and further optimize shielding performance. A further preferred approach is a grid-like integration of multiple soft-magnetic bars that intersect at right angles and thus enable effective shielding in multiple directions.

The aspects and features described in connection with a particular one of the previous examples may also be combined with one or more of the other examples to replace an identical or similar feature of this other example or to introduce the feature additionally into the other example.

Furthermore, it goes without saying that the disclosure of multiple steps, processes, operations or functions disclosed in the description or claims should not be interpreted as necessarily being in the described order, unless this is explicitly stated in the individual case or is mandatory for technical reasons. Therefore, the previous description does not restrict the execution of multiple steps or functions to a specific order. Furthermore, in other examples, a single step, a single function, a single process or a single operation may include and/or be broken into multiple substeps, subfunctions, subprocesses or suboperations.

If some aspects have been described in the preceding sections in connection with a device or system, these aspects are also to be understood as a description of the corresponding method. In this case, for example, a block, a device or a functional aspect of the device or the system may correspond to a feature, such as a method step, of the corresponding method. Correspondingly, aspects described in connection with a method are also to be understood as a description of a corresponding block, a corresponding element, a property or a functional feature of a corresponding device or of a corresponding system.

The following claims are hereby incorporated into the detailed description, each claim being independent as a separate example. It should also be noted that—although a dependent claim in the claims refers to a particular combination with one or more other claims—other examples may also comprise a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

### ASPECTS

The following provides an overview of some Aspects of the present disclosure:

Aspect 1: A magnetoresistive sensor, comprising: a layer stack including: at least one reference layer having a reference magnetization perpendicular to a plane of the layer stack; and at least one free layer having a vortex magnetization; and a soft-magnetic shield arranged adjacent to the layer stack and configured to reduce an influence of an external magnetic field along a shielding axis on the at least one free layer.

Aspect 2: The magnetoresistive sensor as recited in Aspect 1, wherein the soft-magnetic shield is configured to generate an opposing field in response to the external magnetic field.

Aspect 3: The magnetoresistive sensor as recited in any of Aspects 1-2, wherein the soft-magnetic shield is arranged laterally adjacent to the layer stack.

Aspect 4: The magnetoresistive sensor as recited in any of Aspects 1-3, wherein the soft-magnetic shield is arranged above or below the layer stack.

Aspect 5: The magnetoresistive sensor as recited in any of Aspects 1-4, wherein an extent of the soft-magnetic shield that extends perpendicular to the shielding axis is greater than an extent of the soft-magnetic shield that extends parallel to the shielding axis.

Aspect 6: The magnetoresistive sensor as recited in Aspect 5, wherein the extent of the soft-magnetic shield that extends perpendicular to the shielding axis is at least 4 times greater than the extent of the soft-magnetic shield that extends parallel to the shielding axis.

Aspect 7: The magnetoresistive sensor as recited in any of Aspects 1-6, wherein a material of the soft-magnetic shield comprises a nickel-iron alloy, a cobalt-iron alloy, a cobalt-nickel alloy, or an iron-silicon alloy.

Aspect 8: The magnetoresistive sensor as recited in any of Aspects 1-7, wherein a saturation magnetization of a material of the soft-magnetic shield is in a range of 1-1.5 Tesla.

Aspect 9: The magnetoresistive sensor as recited any of Aspects 1-8, wherein the soft-magnetic shield is cuboidal.

Aspect 10: The magnetoresistive sensor as recited in any of Aspects 1-9, wherein the soft-magnetic shield has a first soft-magnetic bar and a second soft-magnetic bar that intersect at right angles.

Aspect 11: The magnetoresistive sensor as recited in any of Aspects 1-10, wherein the soft-magnetic shield has a plurality of soft-magnetic bars arranged in parallel, wherein each soft-magnetic bar of the plurality of soft-magnetic bars has a longitudinal axis running perpendicular or parallel to the shielding axis.

Aspect 12: The magnetoresistive sensor as recited in Aspect 11, wherein a distance between adjacent soft-magnetic bars of the plurality of soft-magnetic bars is greater than 5 μm.

Aspect 13: The magnetoresistive sensor as recited in any of Aspects 1-12, wherein a shortest distance between the layer stack and the soft-magnetic shield is in a range of 0.5-3 μm.

Aspect 14: The magnetoresistive sensor as recited in any of Aspects 1-13, wherein the layer stack comprises a tunneling magnetoresistance (TMR) layer stack.

Aspect 15: The magnetoresistive sensor as recited in any of Aspects 1-14, wherein the layer stack and the soft-magnetic shield are arranged on a common die.

Aspect 16: A bridge circuit, comprising: a plurality of magnetoresistive sensors, wherein each magnetoresistive sensor of the plurality of magnetoresistive sensors includes: a layer stack including: at least one reference layer having a reference magnetization perpendicular to a plane of the layer stack; and at least one free layer having a vortex magnetization; and at least one soft-magnetic shield arranged adjacent to the layer stack and configured to reduce an influence of an external magnetic field along a shielding axis on the at least one free layer.

Aspect 17: A system configured to perform one or more operations recited in one or more of Aspects 1-16.

Aspect 18: An apparatus comprising means for performing one or more operations recited in one or more of Aspects 1-16.

1. A magnetoresistive sensor (500), comprising
a layer stack (510) containing:
at least one reference layer (512) having a reference magnetization perpendicular to the plane of the layer stack; and
at least one free layer (516) having a vortex magnetization; and
at least one soft-magnetic shield (520) arranged adjacent to the layer stack and configured to reduce an influence of an external magnetic field along a shielding axis (530) on the free layer.

2. The magnetoresistive sensor (500) as claimed in claim 1, wherein the shield (520) is configured to generate an opposing field in response to the external magnetic field.

3. The magnetoresistive sensor (500) as claimed in either of the preceding claims, wherein the shield (520) is arranged laterally adjacent to the layer stack (510).

4. The magnetoresistive sensor (500) as claimed in one of the preceding claims, wherein the shield (520) is arranged above or below the layer stack (510).

5. The magnetoresistive sensor (500) as claimed in one of the preceding claims, wherein an extent of the shield (520) perpendicular to the shielding axis (530) is greater than it is parallel to the shielding axis.

6. The magnetoresistive sensor (500) as claimed in claim 5, wherein the extent of the shield (520) perpendicular to the shielding axis (530) is at least 4 times greater than the extent of the shield parallel to the shielding axis.

7. The magnetoresistive sensor (500) as claimed in one of the preceding claims, wherein a material of the shield (520) comprises a nickel-iron alloy, a cobalt-iron alloy, a cobalt-nickel alloy, or an iron-silicon alloy.

8. The magnetoresistive sensor (500) as claimed in one of the preceding claims, wherein a saturation magnetization of a material of the shield (520) is in a range of 1-1.5 Tesla.

9. The magnetoresistive sensor (500) as claimed in one of the preceding claims, wherein the at least one shield (520) is cuboidal.

10. The magnetoresistive sensor (500) as claimed in one of the preceding claims, wherein the shield (520) has a first soft-magnetic bar and a second soft-magnetic bar that intersect at right angles.

11. The magnetoresistive sensor (500) as claimed in one of the preceding claims, wherein the shield (520) has a plurality of soft-magnetic bars arranged in parallel, wherein the bars each have a longitudinal axis running perpendicular or parallel to the shielding axis (530).

12. The magnetoresistive sensor (500) as claimed in claim 11, wherein a distance between adjacent bars is greater than 5 μm.

13. The magnetoresistive sensor (500) as claimed in one of the preceding claims, wherein a shortest distance between the layer stack (510) and the shield (520) is in a range of 0.5-3 μm.

14. The magnetoresistive sensor (500) as claimed in one of the preceding claims, wherein the layer stack (510) comprises a TMR layer stack.

15. The magnetoresistive sensor (500) as claimed in one of the preceding claims, wherein the layer stack (510) and the at least one shield (520) are arranged on a common die.

16. A bridge circuit (900) having a plurality of magnetoresistive sensors as claimed in one of the preceding claims.
